(19) United States
(12) Patent Application Publication
(10) Pub. No.: US 2014/0183741 A1
(43) Pub. Date: Jul. 3, 2014

(54) MASK READ-ONLY MEMORY (ROM) AND METHOD FOR FABRICATING THE SAME

(71) Applicant: SAMSUNG ELECTRONICS CO., LTD., Suwon-si (KR)

(72) Inventor: SANG-HOON PARK, Hwaseong-si (KR)

(73) Assignee: SAMSUNG ELECTRONICS CO., LTD., Suwon-si (KR)

(21) Appl. No.: 14/048,237

(22) Filed: Oct. 8, 2013

(30) Foreign Application Priority Data
Jan. 2, 2013 (KR) 10-2013-0000272

(51) Int. Cl. H01L 23/48

(52) U.S. Cl. CPC H01L 23/481
USPC 257/751

(57) ABSTRACT

A mask ROM includes a plurality of conductive pads disposed on a substrate, an insulating film disposed on the conductive pads, a plurality of via holes disposed in the insulating film exposing the conductive pads, a plurality of first wirings disposed side by side and spaced apart from each other on the insulating film, a plurality of vias disposed in the via holes electrically connecting the conductive pads to the first wirings, respectively, and a plurality of barrier conductive films disposed on a bottom surface of a part of the plurality of via holes between the vias and the conductive pads.

### CROSS-REFERENCE TO RELATED APPLICATIONS

This application claims priority from Korean Patent Application No. 10-2013-0000272, filed on Jan. 2, 2013, the disclosure of which is hereby incorporated by to reference herein in its entirety.

### TECHNICAL FIELD

The present disclosure relates to a mask ROM and a method for fabricating the same.

### DISCUSSION OF THE PRIOR ART

A semiconductor memory device may be classified into a nonvolatile memory device in which stored data is not lost even if a power supply is interrupted and a volatile memory device in which stored data is destructed if the power supply is interrupted.

In accordance with data storage methods, a nonvolatile memory device may be classified into, for example, a mask ROM in which a user is unable to change data, and a PROM (Programmable ROM), an OTPROM (One Time Programmable ROM), an EPROM (Electrically Programmable ROM), an EEPROM (Electrically Erasable and Programmable ROM), or the like, in which the user can change data.

Among such nonvolatile memory devices, a mask ROM is a device which stores data through coding using a mask that has data desired by a user. Once the data is stored in such a mask ROM, it may not be possible to change the data stored therein, but it may be possible to read the data only.

In a system in which such a mask ROM is used and security is desired, it is may be necessary to prevent code data stored in the mask ROM from being hacked.

### SUMMARY

Exemplary embodiments of the present invention provide a mask ROM which can strengthen the security to prevent code data stored in the mask ROM from being hacked.

Exemplary embodiments of the present invention provide a method for fabricating the mask ROM.

According to an exemplary embodiment of the present invention, there is provided a mask ROM including a plurality of conductive pads disposed on a substrate, an insulating film disposed on the conductive pads, a plurality of via holes disposed in the insulating film exposing the conductive pads, a plurality of first wirings disposed side by side and spaced apart from each other on the insulating film, a plurality of vias disposed in the via holes electrically connecting the conductive pads to the first wirings, respectively, and a plurality of barrier conductive films disposed on a bottom surface of a part of the plurality of via holes between the vias and the conductive pads.

According to an exemplary embodiment of the present invention, there is provided a mask ROM including a first conductive pad and a second conductive pad disposed on a substrate, an insulating film disposed on the first conductive pad and the second conductive pad, a first via hole and a second via hole disposed in the insulating film exposing the first conductive pad and the second conductive pad, a plurality of first wirings disposed side by side and spaced apart from each other on the insulating film, a first via disposed in the first via hole electrically connecting the first conductive pad to the first wirings, a second via disposed in the second via hole electrically connecting the second conductive pad to the first wirings, a first barrier conductive film disposed on a bottom surface of the first via hole between the first via and the first conductive pad, and having a first thickness, and a second barrier conductive film disposed on a bottom surface of the second via hole between the second via and the second conductive pad, and having a second thickness that is different from the first thickness.

In accordance with an exemplary embodiment of the present invention, a mask ROM includes a first conductive pad and a second conductive pad disposed on a substrate, an interlayer insulating film disposed on the first conductive pad and the second conductive pad, a first via hole and a second via hole disposed in the interlayer insulating film exposing the first conductive pad and the second conductive pad, a plurality of first wirings disposed side by side and spaced apart from each other on the insulating film, a first via disposed in the first via hole electrically connecting the first conductive pad to the first wirings, a second via disposed in the second via hole electrically connecting the second conductive pad to the first wirings, and a first barrier conductive film including a first lower bottom barrier conductive film and a first upper bottom barrier conductive film sequentially disposed on a bottom surface of the first via hole between the first via and the first conductive pad and a first lower side barrier conductive film and a first upper side barrier conductive film sequentially disposed on opposing side surfaces of the first via hole between the first via and the interlayer insulating film.

In addition, the mask ROM further includes a second barrier conductive film including a second lower bottom barrier conductive film disposed on a bottom surface of the second via hole between the second via and second conductive pad and a second lower side barrier conductive film and a second upper side barrier conductive barrier sequentially disposed on opposing side surfaces of the second via hole between the second via and the interlayer insulating film. A thickness of the first lower bottom barrier conductive film and the first upper bottom barrier conductive film sequentially disposed on the bottom surface of the first via hole is larger than a thickness of the second lower bottom barrier conductive film disposed on the bottom surface of the second via hole.

### BRIEF DESCRIPTION OF THE DRAWINGS

Exemplary of the present invention can be understood in more detail from the following detailed description taken in conjunction with the accompanying drawings, in which:

FIG. 1 is a schematic circuit diagram explaining a mask ROM according to an embodiment of the present invention;

FIG. 2 is a plan view explaining a mask ROM according to an embodiment of the present invention;

FIG. 3 is a cross-sectional view explaining a mask ROM according to an embodiment of the present invention;

FIG. 4 is a cross-sectional view explaining a mask ROM according to an embodiment of the present invention;

FIG. 5 is a cross-sectional view explaining a mask ROM according to an embodiment of the present invention;

FIG. 6 is a cross-sectional view explaining a mask ROM according to an embodiment of the present invention;

FIG. 7 is a cross-sectional view explaining a mask ROM according to an embodiment of the present invention;

FIGS. 8 to 12 are view of intermediate steps explaining a method for fabricating a mask ROM according to an embodiment of the present invention; and

FIGS. 13 to 15 are view of intermediate steps explaining a method for fabricating a mask ROM according to an embodiment of the present invention.

### DETAILED DESCRIPTION OF EXEMPLARY EMBODIMENTS

Exemplary embodiments of the present invention will now be described more fully hereinafter with reference to the accompanying drawings, in which preferred embodiments of the invention are shown. Exemplary embodiments of the invention may, however, be embodied in different forms and should not be construed as limited to embodiments set forth herein. The same reference numbers indicate the same components throughout the specification. In the attached figures, the thickness of layers and regions may be exaggerated for clarity.

It will be understood that when an element or layer is referred to as being “connected to,” or “coupled to” another element or layer, it can be directly connected to or coupled to another element or layer or intervening elements or layers may be present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

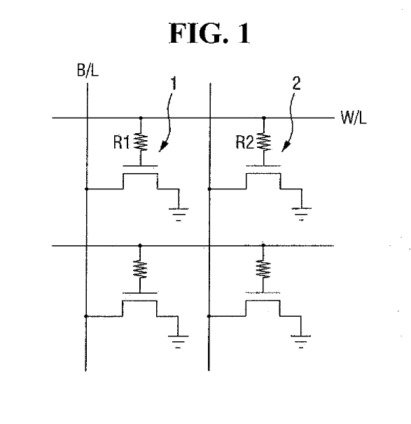

Hereinafter, an operation of a mask ROM according to embodiments of the present invention will be described with reference to FIG. 1.

FIG. 1 is a schematic circuit diagram explaining a mask ROM according to embodiments of the present invention.

For example, referring to FIG. 1, in a cell structure of a mask ROM, at least a first transistor 1 and a second transistor 2 may be formed. A word line W/L may be connected to, for example, a gate electrode of the first transistor 1 and a gate electrode of the second transistor 2. A bit line B/L may be connected to, for example, a drain of the first transistor 1 and a drain of the second transistor 2, and sources of the first transistor 1 and the second transistor 2 may be grounded. However, this is merely exemplary, and the cell structure is not limited thereto. That is, alternatively, in an embodiment, the sources of the first transistor 1 and the second transistor 2 may be connected to, for example, the bit line BL. Further, alternatively, in an embodiment, the sources of the first transistor 1 and the second transistor 2 may not be connected to ground, but may be connected to, for example, a wiring that supplies constant voltage.

For example, a first wiring resistance between the gate electrode of the first transistor 1 and the word line W/L may be R1, and second wiring resistance between the gate electrode of the second transistor 2 and the word line W/L may be R2. In the mask ROM according to embodiments of the present invention, the first wiring resistance R1 and the second wiring resistance R2 are, for example, different from each other.

In accordance with a gate voltage that is applied to the first transistor 1, an operation/non-operation of the first transistor 1 is determined. In the same manner, in accordance with a gate voltage that is applied to the second transistor 2, an operation/non-operation of the second transistor 2 is determined. In this case, if the voltage that is applied to the word line W/L is kept constant, the gate voltage that is applied to the transistor may differ depending on the wiring resistance that exists between the word line W/L and the gate electrode of the transistor. That is, if the wiring resistance that exists between the word line W/L and the gate electrode of the transistor becomes high, the gate voltage that is applied to the transistor may be decreased. By contrast, if the wiring resistance that exists between the word line W/L and the gate electrode of the transistor becomes low, the gate voltage that is applied to the transistor may be increased.

Explanation will be made under the assumption that the first wiring resistance R1 between the gate electrode of the first transistor 1 and the word line. W/L is higher than the second wiring resistance R2 between the gate electrode of the second transistor 2 and the word line W/L.

As the first wiring resistance R1 is higher than the second wiring resistance R2, the voltage drop caused by the first wiring resistance R1 becomes greater than the voltage drop caused by the second wiring resistance R2. In other words, as the first wiring resistance R1 is higher than the second wiring resistance R2, the gate voltage that is applied to the first transistor 1 becomes lower than the gate voltage that is applied to the second transistor 2. In this case, although the first transistor 1 and the second transistor 2 are electrically connected to the same word line W/L, the second transistor 2 is turned on and thus current flows to the channel of the second transistor, while the first transistor 1 is not turned on and thus current may not flow to the channel of the first transistor 1. Further, although the first transistor 1 and the second transistor 2 are all turned on, the current flowing to the channel of the second transistor 2 may be larger than the current flowing to the channel of the first transistor 1.

Signal amplifiers S/A, which are respectively connected to the first transistor 1 and the second transistor 2 through the bit line B/L, can sense the current flowing to the channel of the first transistor 1 and the current flowing to the channel of the second transistor 2, respectively. As the first wiring resistance R1 and the second wiring resistance R2 are different from each other, the amount of current sensed by the signal amplifier connected to the first transistor 1 may be different from the amount of current sensed by the signal amplifier connected to the second transistor 2.

In the mask ROM according to an embodiment of the present invention, by making the resistances R1 and R2 between the word line W/L and the transistors 1 and 2 different from each other, the amounts of current sensed by the signal amplifiers connected to the bit line B/L may be different from each other, and through this, a memory cell of the mask ROM can be coded.

In the foregoing description, it is described that there is a difference between the currents detected by the signal amplifiers, but exemplary embodiments of the present invention are not limited thereto. That is, even if the same current is detected by the signal amplifiers, the difference between the first wiring resistance R1 and the second wiring resistance R2 can be known through the sensing of a time interval until the same current is detected. Even in this case, the data coded in the memory cell of the mask ROM can be extracted.

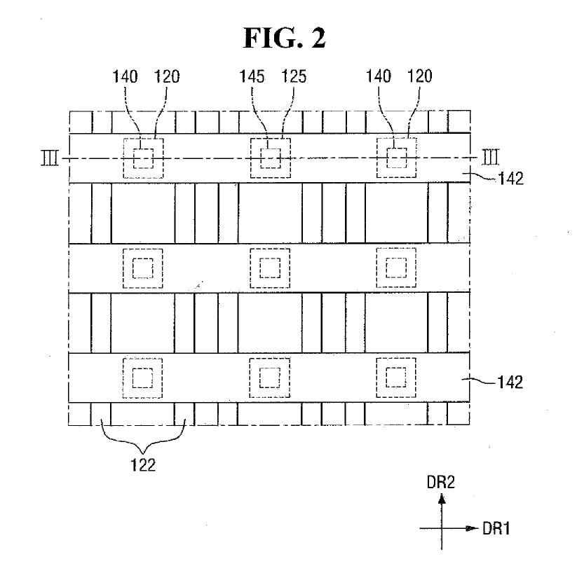

Referring to FIG. 2, a mask ROM according to embodiments of the present invention will be described.

FIG. 2 is a plan view explaining a mask ROM according to embodiments of the present invention.

Referring to FIG. 2, a plurality of first wirings 142 may be formed in a first direction DR1. The plurality of first wiring 142 may be formed, for example, side by side and spaced apart from each other. A plurality of second wirings 122 may be formed in a second direction DR2. The second wirings 122 may be formed, for example, to cross the first wirings 142, and may be formed side by side and spaced apart from each other. A pair of second wirings 122 may be connected to a source and a drain of a transistor formed on a lower portion thereof. Although it is explained that the pair of second wirings 122 are connected to the transistor formed on the lower portion, this is merely exemplary, and the configuration of the second wirings 122 is not limited thereto. That is, alternatively, in an embodiment, an adjacent transistor may, for example, share the source or the drain, and in this case, the pair of second wirings 122 may not be provided.

A plurality of conductive pads 120 and 125 may be formed on, for example, a lower portion of the first wiring 142. Further, the plurality of conductive pads 120 and 125 may be formed, for example, between a pair of second wirings. Among the plurality of conductive pads 120 and 125, the conductive pads 120 and 125 disposed in the first direction DR1 may be electrically connected to one first wiring 142. The respective conductive pads 120 and 125 disposed in the first direction DR1 may be connected to, for example, the corresponding first wiring 142 through vias 140 and 145.

Gate patterns that correspond to the conductive pads 120 and 125 may be formed on, for example, the lower portions of the respective conductive pads 120 and 125. The gate patterns, the conductive pads 120 and 125, and the vias 140 and 145 may be formed to, for example, overlap each other. The conductive pads 120 and 125 and the vias 140 and 145, which are formed to overlap each other, constitute one memory cell.

In the mask ROM according to embodiments of the present invention, the first wiring 142 may be, for example, a word line, and the second wiring 122 may be, for example, a bit line.

In a plan view of the mask ROM according to embodiments of the present invention, each memory cell of the mask ROM includes, for example, a gate pattern, conductive pads 120 and 125, and vias 140 and 145. However, different data are coded in the respective memory cells of the mask ROM. Through this, the mask ROM according to embodiments of the present invention can significantly strengthen the security, and data coded in the memory cells of the mask ROM can be relatively easily extracted through reverse engineering.

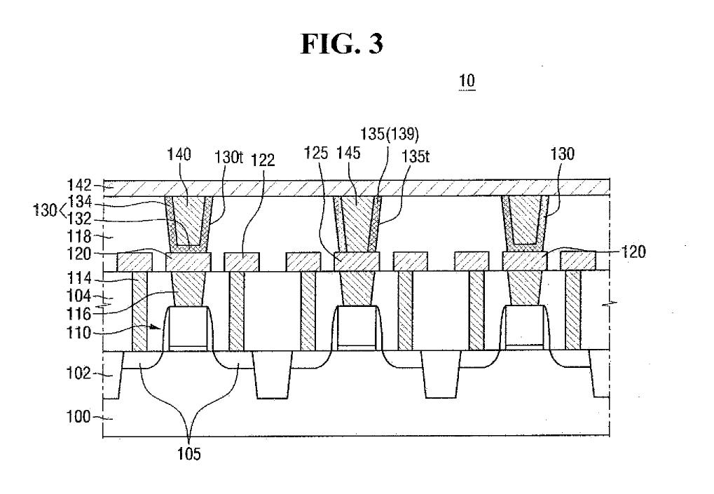

Referring to FIGS. 2 and 3, a mask ROM according to an embodiment of the present invention will be described.

FIG. 3 is a cross-sectional view explaining a mask ROM according to an embodiment of the present invention. FIG. 3 is a cross-sectional view cut along line III-III in FIG. 2.

Referring to FIG. 3, a mask ROM 10 includes, for example, a plurality of conductive pads 120 and 125, an interlayer insulating film 118, a plurality of vias 140 and 145, a first barrier conductive film 130, a second barrier conductive film 135, and first wirings 142.

An isolation film 102, which defines an active region on which a gate pattern 110 is formed, is formed in the substrate 100. The substrate 100 may be made of, for example, bulk silicon or SOI (Silicon-On-Insulator). Further, the substrate 100 may be a silicon substrate, or may include another material such as, for example, silicon germanium, indium antimonide, lead telluride, indium arsenide, indium phosphide, gallium arsenide, or gallium antimonide, but exemplary embodiments of the present invention are not limited thereto. For example, the isolation film 102 may be FOX (Field Oxide) or STI (Shallow Trench Isolation) using a LOCOS (Local Oxidation of Silicon) method. Although FIG. 3 illustrates that one gate pattern 100 is formed between the isolation films 102, this is merely exemplary, and exemplary embodiments of the present invention are not limited thereto. If gate patterns 110 share the source or the drain, there is no doubt that a plurality of gate patterns 110 may be formed between the isolation films 102.

The gate pattern 110 is formed in the active region that is defined by the isolation film 102. The gate pattern 110 includes, for example, a gate insulating film and a gate electrode. The gate insulating film may be, for example, a silicon oxide film, silicon oxynitride (SiON), germanium oxynitride (GexOyNz), germanium silicon oxide (GexSiyOz), a high-k dielectric film, a mixture thereof, or a stacked film in which the above-described materials are stacked in order. The high-k dielectric film may include, for example, at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but exemplary embodiments of the present invention are not limited thereto. The gate electrode may be made of, for example, silicon. For example, in an embodiment, the gate electrode may be made of poly silicon (poly Si) or amorphous silicon (a-Si). However, exemplary embodiments of the present invention are not limited to the above-mentioned materials for the gate electrode. For example, alternatively, in an embodiment, the gate electrode may be, for example, a metal electrode including a metal material.

A source/drain 105 may be formed on both sides of the gate pattern 110, and an impurity that is different from that of the substrate 100 may be doped thereon. In the mask ROM according to an embodiment of the present invention, transistors formed on the substrate 100 may be, for example, of the same kind. For example, if the transistor is a PMOS transistor, a p-type impurity is doped on the source/drain 105, and if the transistor is an NMOS transistor, an n-type impurity is doped on the source/drain 105.

A pre-metal dielectric layer 104 is formed on the substrate 100 and the gate pattern 110. The pre-metal dielectric layer 104 may be made of a low-k material such as, for example, FOX (Flowable Oxide), TOSZ (Tonen SilaZen), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), HDP (High Density Plasma), PEOX (Plasma Enhanced Oxide), FCVD (Flowable CVD), or a combination thereof.

A plurality of conductive pads 120 and 125 may be formed on the pre-metal dielectric layer 104. The plurality of conductive pads 120 and 125 fanned on the substrate 100 may be formed, for example, spaced apart from each other, and may be disposed in a matrix form. The conductive pads 120 and 125 may include, for example, the first conductive pad 120 and the second conductive pad 125. In accordance with the shape of a barrier conductive film that is formed on an upper portion or a lower portion of the conductive pad 120 and 125, the first conductive pad 120 and the second conductive pad 125 may discriminate against each other. The conductive pads 120 and 125 may include, for example, at least one of aluminum, tungsten, and copper.

Second wirings 122 may be further formed on the pre metal dielectric layer 104 on the substrate 100. The second wirings 122 may be formed, for example, side by side and spaced apart from each other. The second wirings 122 may include, for example, one of aluminum and copper. In the mask ROM according to embodiments of the present invention, it is described that the second wirings 122 are formed on the pre-metal dielectric layer 104, but exemplary embodiments of the present invention are not limited thereto.

The plurality of conductive pads 120 and 125 may be electrically connected to, for example, the plurality of gate patterns 110 formed on lower portions thereof. Through first contacts 116 formed in the pre-metal dielectric layer 104, the respective conductive pads 120 and 125 may be connected to, for example the corresponding gate patterns 110. Further, the second wirings 122 may be electrically connected to, for example, the source/drain 105 formed on lower portions thereof. Through second contacts 114 formed in the pre-metal dielectric layer 104, the respective second wirings 122 may be connected to, for example, the corresponding source/drain 105. Barrier conductive films (not illustrated) may be further formed, for example, between the first contact 116 and the pre-metal dielectric layer 104 and between the second contact 114 and the pre-metal dielectric layer 104. The first contact 116 and the second contact 114 may include, for example, one of tungsten and aluminum.

The interlayer insulating film 118 may be formed on, for example, the plurality of conductive pads 120 and 125 and the second wirings 122. The interlayer insulating film 118 may include, for example, a plurality of via holes 130t and 135t formed in the inter layer insulating film 118, and the conductive pads 120 and 125 may be exposed through the via holes 130t and 135t. For example, the via holes 130t and 135t include the first via hole 130t and the second via hole 135t. The first via hole 130t may expose the first conductive pad 120, and the second via hole 135t may expose the second conductive pad 125. The interlayer insulating film 118 may include, for example, at least one of silicon oxide, silicon nitride, and silicon oxynitride, or may include a low-k material.

The first wirings 142 are formed on, for example, the interlayer insulating film 118. As shown in FIG. 2, the plurality of first wirings 142 may be formed, for example, side by side and spaced apart from each other. The first wirings 142 may include, for example, one of aluminum and copper.

The plurality of vias 140 and 145 are formed, for example, in the plurality of via holes 130t and 135t, respectively. The plurality of vias 140 and 145 may electrically connect the plurality of corresponding conductive pads 120 and 125 to the first wirings 142. For example, the first via 140 formed in the first via hole 130t may electrically connect the first conductive pad 120 on the lower portion of the first via hole 130t to the first wiring 142 on the upper portion of the first via hole 130t, and the second via 145 formed in the second via hole 135t may electrically connect the second conductive pad 125 on the lower portion of the second via hole 135t to the first wiring 142 on the upper portion of the second via hole 135t.

The plurality of vias 140 and 145 may include, for example, at least one of tungsten and copper. The first via 140 and the second via 145 may include, for example, substantially the same material as each other.

The first barrier conductive film 130 may be formed, for example, in the first via hole 130t, and the second barrier conductive film 135 may be formed, for example, in the second via hole 135t. The first barrier conductive film 130 and the second barrier conductive film 135 may include, for example, a material, such as tantalum (Ta), tantalum nitride (TaN), titanium (Ti), titanium nitride (TiN), ruthenium (Ru), cobalt (Co), nickel (Ni), nickel boron (NiB), and tungsten nitride (WN). The first barrier conductive film 130 and the second barrier conductive film 135 may include, for example, substantially the same material as each other. Although the first barrier conductive film 130 and the second barrier conductive film 135 are illustrated as a single layer in the present embodiment, exemplary embodiments of the present invention are not limited thereto. For example, alternatively in an embodiment, the first barrier conductive film 130 and the second barrier conductive film 135 may include a plurality of layers.

The first barrier conductive film 130 includes, for example, a first side barrier conductive film 134 formed on a side surface of the first via hole 130t and a first bottom barrier conductive film 132 formed on a bottom surface of the first via hole 130t. The second barrier conductive film 135 is not formed on a bottom surface of the second via hole 135t, but a second side barrier conductive film 139 is formed only on a side surface of the second via hole 135t. That is, the second barrier conductive film 135 may include, for example, only the second side barrier conductive film 139. In other words, the barrier conductive films 130 and 135 interposed between the vias 140 and 145 and the conductive pads 120 and 125 may be formed, for example, on the bottom surface of a part of the plurality of via holes 130t and 135t, but may not be formed on the bottom surface of the remaining via hole.

For example, the first barrier conductive film 130 formed in the first via hole 130t is interposed between the first via 140 and the first conductive pad 120, and is formed on the bottom surface of the first via holes 130t. However, the second barrier conductive film 135 formed in the second via hole 135t is interposed between the second via 145 and the interlayer insulating film 118, but is not formed on the bottom surface of the second via hole 135t. In the present embodiment, the second barrier conductive film 135 is not interposed between the bottom surface of the second via 145 and the second conductive pad 125.

In the mask ROM according to the present embodiment of the present invention, the first bottom barrier conductive film 132 is formed on the bottom surface of the first via hole 130t, but the second barrier conductive film 135 is not formed on the bottom surface of the second via hole 135t.

Referring to FIG. 3, in the second via hole 135t having the bottom surface on which the second barrier conductive film 135 is not formed, the second via 145 may be formed, for example, to be in contact with the second conductive pad 125.

In the first via hole 130t having the bottom surface on which the first barrier conductive film 130 is formed, the resistance between the first wiring 142 and the first conductive pad 120 may be a first resistance, and in the second via hole 135t having the bottom surface on which the second barrier conductive film 135 is not formed, the resistance between the first wiring 142 and the second conductive pad 125 may be a second resistance. If a material that is used as the first barrier conductive film 130 and the second barrier conductive film 135 is different from a material that is used as the vias 140 and 145, the first resistance in the first via hole 130t may be different from the second resistance in the second via hole 135t. If the resistivity of the material that is included in the first barrier conductive film 130 and the second barrier conductive film 135 is higher than the resistivity of the material that is included in the vias 140 and 145, the first resistance in the first via hole 130t is higher than the second resistance in the second via hole 135t. This is because the first bottom barrier conductive film 132 having high resistivity is interposed between the first conductive pad 120 and the first via 140.

Hereinafter, coding of memory cells in the mask ROM depending on the existence/nonexistence of the barrier conductive film on the bottom surface of the via hole will be described.

It is assumed that a memory cell that includes the first via 140 and the first conductive pad 120 is called a first memory cell, and a memory cell that includes the second via 145 and the second conductive pad 125 is called a second memory cell. In the case of the first memory cell, a significant voltage drop may occur due to the existence of the first bottom barrier conductive film 132 while current flows from the first wiring 142 to the gate electrode of the gate pattern 110 through the first conductive pad 120. However, in the case of the second memory cell, a voltage drop that is smaller than that in the first memory cell may occur due to the nonexistence of the second barrier conductive film 135 between the second via 145 and the second conductive pad 125 while current flows from the first wiring 142 to the gate electrode of the gate pattern 110 through the second conductive pad 125. If the levels of the voltage drop differ from each other as described above, they may exert influences on the operations of the respective gate patterns 110 which are on the lower portions of the first conductive pad 120 and the second conductive pad 125. That is, the gate pattern 110 included in the first memory cell may not operate but the gate pattern 110 included in the second memory cell may operate, such that current may not flow through the second wiring 122 included in the first memory cell and current may flow through the second wiring 122 included in the second memory cell.

That is, the memory cells included in the mask ROM may be coded with different values depending on the existence/nonexistence of the barrier conductive film between the vias 140 and 145 and the conductive pads 120 and 125.

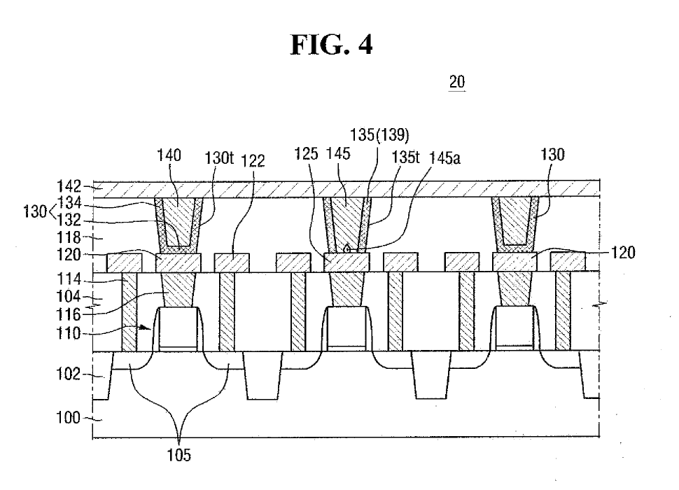

Referring to FIGS. 2 and 4, a mask ROM according to an embodiment of the present invention will be described. The present embodiment is substantially the same as the mask ROM described above in connection with FIG. 3 except for the point that an air gap is included according to the present embodiment. Thus, the same reference numerals used in connection with the mask ROM of FIG. 3 are used in the present embodiment to refer to the same elements, and an explanation thereof will be simplified or omitted.

FIG. 4 is a cross-sectional view explaining a mask ROM according to an embodiment of the present invention. FIG. 4 is a cross-sectional view cut along line III-III in FIG. 2.

Referring to FIG. 4, a mask ROM 20 includes, for example, a plurality of conductive pads 120 and 125, an interlayer insulating film 118, a plurality of vias 140 and 145, a first barrier conductive film 130, a second barrier conductive film 135, and an air gap 145a.

The plurality of conductive pads 120 and 125 formed on a pre-metal dielectric layer 104 are electrically connected to, for example, corresponding gate patterns 110 on the lower portions. A plurality of first wirings 142 are formed on, for example, the plurality of conductive pads 120 and 125. The plurality of vias 140 and 145, for example, electrically connect the plurality of corresponding conductive pads 120 and 125 to the first wirings 142. That is, the first via 140 may electrically connect the first wiring 142 to the first conductive pad 120, and the second via 145 electrically connect the first wiring 142 to the second conductive pad 125.

The first barrier conductive film 130, specifically, a first bottom barrier conductive film 132, is formed between the bottom surface of the first via 140 and the first conductive pad 120. However, the second barrier conductive film 135 is, for example, not formed between the bottom surface of the second via 145 and the second conductive pad 125.

The air gap 145a may be formed, for example, in the via hole having a bottom surface on which the second barrier conductive film 135 is not formed. For example, the air gap 145a may be formed in the second via hole 135t in which the second barrier conductive film 135 is not formed between the bottom surface of the second via 145 and the second conductive pad 125.

Through the second via 145 including the air gap 145a, the first wiring 142 and the gate pattern 110 that is positioned on the lower portion of the second conductive pad 125 may be electrically connected to each other.

By forming the air gap 145a in the second via 145 formed in the second via hole 135t, the resistance between the first wiring 142 and the second conductive pad 125 may be changed. Through this, different data can be coded in the memory cells of the mask ROM.

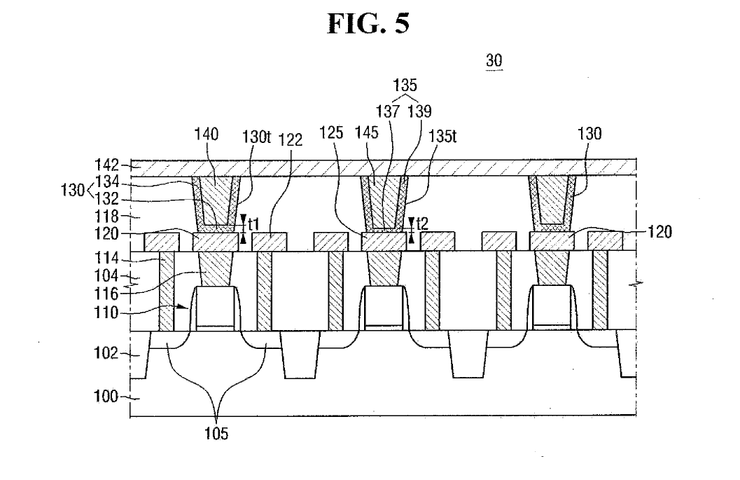

Referring to FIGS. 2 and 5, a mask ROM according to an embodiment of the present invention will be described. The same reference numerals used in connection with the mask ROM of FIG. 3 are used in the present embodiment to refer to the same elements, and an explanation thereof will be simplified or omitted.

FIG. 5 is a cross-sectional view explaining a mask ROM according to an embodiment of the present invention. FIG. 5 is a cross-sectional view cut along line III-III in FIG. 2.

Referring to FIG. 5, a mask ROM 30 includes, for example, a plurality of conductive pads 120 and 125, an interlayer insulating film 118, a plurality of vias 140 and 145, a first barrier conductive film 130, a second barrier conductive film 135, and first wirings 142.

The first via 140, which is electrically connected to the first conductive pad 120, is formed in a first via hole 130t that exposes the first conduction pad 120. The first barrier conductive film 130 is, for example, interposed between the first via hole 130t and the first via 140. The second via 145, which is electrically connected to the second conductive pad 125, is formed in, for example, a second via hole 135t that exposes the second conductive pad 125. The second barrier conductive film 135 is, for example, interposed between the second via hole 135t and the second via 145.

The first barrier conductive film 130 includes, for example, a first side barrier conductive film 134 formed on a side surface of the first via hole 130t, and a first bottom barrier conductive film 132 formed on a bottom surface of the first via hole 130t. The second barrier conductive film 135 includes, for example, a second side barrier conductive film 139 formed on a side surface of the second via hole 135t, and a second bottom barrier conductive film 137 formed on a bottom surface of the second via hole 135t. As the first side barrier conductive film 134 and the second side barrier conductive film 139 are formed at the same level, they may have substantially the same thickness as each other. Here, “the same level” means that they are formed by the same fabricating process. Further, “the same thickness” means that not only the widths at two compared positions are completely the same but also the widths include a minute difference in thickness that may occur due to a margin on the fabricating process.

Referring to FIG. 5, the thickness of the first barrier conductive film 130, which is formed on the bottom surface of the first via hole 130t and is interposed between the first via 140 and the first conductive pad 120, becomes a first width t1. However, the thickness of the second barrier conductive film 135, which is formed on the bottom surface of the second via hole 135t and is interposed between the second via 145 and the second conductive pad 125 becomes a second thickness t2 that is, for example, different from the first thickness t1.

For example, the thickness of the first bottom barrier conductive film 132 that is formed on the bottom surface of the first via hole 130t is the first thickness t1, and the thickness of the second bottom barrier conductive film 137 that is formed on the bottom surface of the second via hole 135t is the second thickness t2.

For example, in the mask ROM according to the present embodiment of the present invention, the first barrier conductive film 130 and the second barrier conductive film 135 may include substantially the same material as each other, and may be formed as a single layer. Accordingly, although the first bottom barrier conductive film 132 and the second bottom barrier conductive film 137 have different thicknesses, they may be formed as a single layer, and may include substantially the same material.

In the mask ROM according to the present embodiment of the present invention, the first thickness t1 of the first barrier conductive film 130 that is formed on the bottom surface of the first via hole 130t is, for example, larger than the second thickness t2 of the second barrier conductive film 135 that is formed on the bottom surface of the second via hole 135t. That is, the thickness of the first bottom barrier conductive film 132 is larger than the thickness of the second barrier conductive film 135. If the resistivity of the conductive material that forms the barrier conductive films 130 and 135 and the resistivity of the conductive material that forms the vias 140 and 145 are different from each other, the first resistance between the first wiring 142 and the first conductive pad 120 is different from the second resistance between the first wiring 142 and the second conductive pad 125.

In the mask ROM according to the present embodiment of the present invention, it is described that the resistivity of the material that forms the barrier conductive films 130 and 135 is higher than the resistivity of the material that forms the vias 140 and 145, but exemplary embodiments of the present invention are not limited thereto. As the thickness t1 of the first bottom barrier conductive film 132 that is interposed between the first via 140 and the first conductive pad 120 is larger than the thickness t2 of the second bottom barrier conductive film 137 that is interposed between the second via 145 and the second conductive pad 125, the first resistance between the first wiring 142 and the first conductive pad 120 is higher than the second resistance between the first wiring 142 and the second conductive pad 125.

As described above, by making the thicknesses of the first barrier conductive film 130 and the second barrier conductive film 135, which are respectively formed on the bottom surfaces of the first via hole 130t and the second via hole 135t, different from each other, the resistance value between the gate electrode of the gate pattern 110 and the first wiring 142 can be adjusted. Through this, the memory cells included in the mask ROM can be coded with different values.

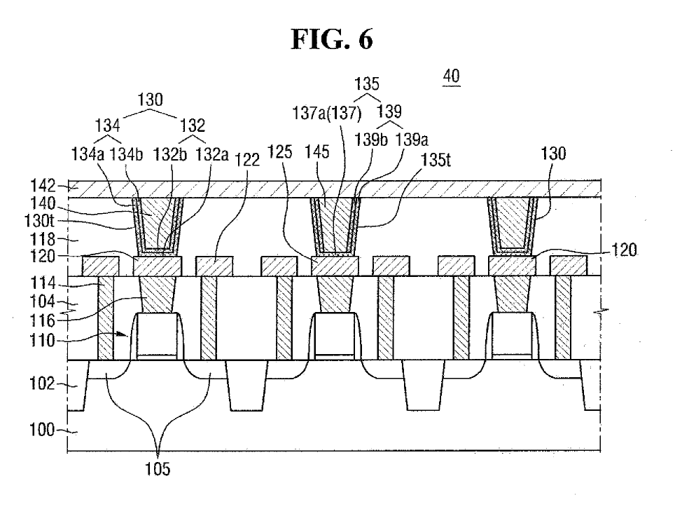

Referring to FIGS. 2 and 6, a mask ROM according to an embodiment of the present invention will be described. The mask ROM of the present embodiment is substantially the same as the mask ROM as described above in connection with FIG. 5 except for the point that a barrier conductive film includes a plurality of layers according to the present embodiment. Thus, the same reference numerals used in connection with the mask ROM of FIG. 5 are used in the present embodiment to refer the same elements, and an explanation thereof will be simplified or omitted.

FIG. 6 is a cross-sectional view explaining a mask ROM according to an embodiment of the present invention. FIG. 6 is a cross-sectional view cut along line III-III in FIG. 2.

Referring to FIG. 6, a mask ROM 40 includes, for example, a plurality of conductive pads 120 and 125, an interlayer insulating film 118, a plurality of vias 140 and 145, a first barrier conductive film 130, a second barrier conductive film 135, and first wirings 142.

The first barrier conductive film 130 includes, for example, a first upper bottom barrier conductive film 132b, a first upper side barrier conductive film 134b, a first lower bottom barrier conductive films 132a and a first lower side barrier conductive film 134a. The second barrier conductive film 135 includes, for example, a second upper side barrier conductive film 139b, second lower bottom barrier conductive film 137a and a second lower side barrier conductive film 139a. The first upper bottom barrier conductive film 132b and the first upper side barrier conductive film 134b and the second upper side barrier conductive film 139b include, for example, substantially the same material as each other. In addition, the first lower bottom barrier conductive film 132a and the first lower side barrier conductive film 134a and the second lower bottom barrier conductive film 137a and the second lower side barrier conductive film 139a include, for example, substantially the same material as each other. The first lower bottom barrier conductive film 132a and the first lower side barrier conductive film 134a and the first upper bottom barrier conductive film 132b and the first upper side barrier conductive film 134b include, for example, different materials from each other.

The first lower bottom barrier conductive film 132a and the first upper bottom barrier conductive film 132b are, for example, sequentially formed on the bottom surface of the first via hole 130t, and the first lower side barrier conductive film 134a and the first upper side barrier conductive film 134b are, for example, sequentially formed on the side surface of the first via hole 130t. The second lower side barrier conductive film 139a and the second upper side barrier conductive film 139b are, for example, sequentially formed on the side surface of the second via hole 135t. However, the second lower bottom barrier conductive film 137a is, for example, formed on the bottom surface of the second via hole 135t, but a second upper bottom barrier conductive film is not formed on the bottom surface of the second via hole 135t.

That is, the first barrier conductive film 130, which includes the first lower bottom barrier conductive film 132a, the first lower side barrier conductive film 134a, the first upper bottom barrier conductive film 132b and the first upper side barrier conductive film 134b, is formed on the bottom surface of the first via hole 130t. However, only the second barrier conductive film 135, which does not include the second upper side barrier conductive film 139b, that is the second lower bottom barrier conductive film 137a and the second lower side barrier conductive film 139a, is formed on the bottom surface of the second via hole 135t.

In other words, the first barrier conductive film 130, which includes the first film and the second film, is formed on the bottom surface of the first via hole 130t, but the second barrier conductive film 135, which does not include the second film, is formed on the bottom surface of the second via hole 135t. Accordingly, the thickness of the first barrier conductive film 130 that is formed on the bottom surface of the first via hole 130t is larger than the thickness of the second barrier conductive film 135 that is formed on the bottom surface of the second via hole 135t.

By forming the additional barrier conductive film on the bottom surface of the first via hole 130t, the thicknesses of the first bottom barrier conductive film 132 and the second bottom barrier conductive film 137 become different from each other, and the resistance value between the gate electrode of the gate pattern 110 and the first wiring 142, which constitute each memory cell, can be adjusted. Through this, the memory cells included in the mask ROM can be coded with different values.

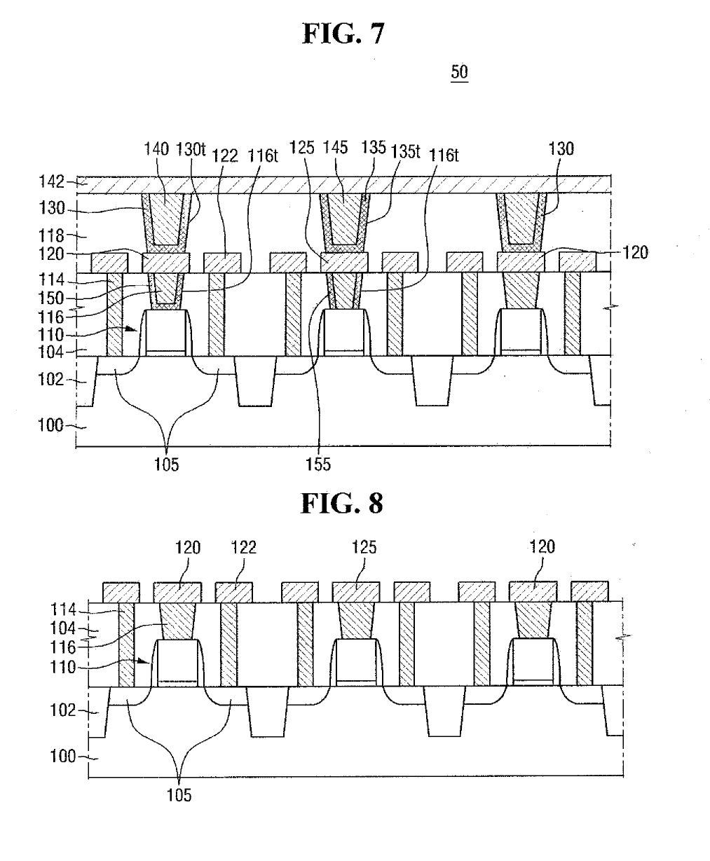

Referring to FIGS. 2 and 7, a mask ROM according to an embodiment of the present invention will be described. The present embodiment is substantially the same as the mask ROM described above in connection with FIG. 3 except for the inclusion of a third barrier conductive film and a fourth bather conductive film to the present embodiment. Thus, the same reference numerals used in connection with the mask ROM of FIG. 3 are used in the present embodiment to refer to the same elements, and an explanation thereof will be simplified or omitted.

FIG. 7 is a cross-sectional view explaining a mask ROM according to an embodiment of the present invention. FIG. 7 is a cross-sectional view cut along line III-III in FIG. 2.

Referring to FIG. 7, a mask ROM 50 includes, for example, gate patterns 110, a plurality of conductive pads 120 and 125, first contacts 116, a third barrier conductive film 150, and a fourth barrier conductive film 155.

The plurality of gate patterns 110 are formed on the substrate 100, and are isolated by an isolation film 102. A source/drain 105 is formed on both sides of each gate pattern 110. In the mask ROM according to the present embodiment of the present invention, it is described that the source/drain 105 is formed on both sides of the gate pattern 110, but exemplary embodiments of the present invention are not limited thereto. That is, for example, two gate patterns 110 may share one drain.

A pre-metal dielectric layer 104 is formed on the substrate 100 and the gate pattern 110. The pre-metal dielectric layer 104 may include, for example, at least one of silicon oxide, silicon nitride, and silicon oxynitride, or may include a low-k material.

The pre-metal dielectric layer 104 may include, for example, a plurality of contact holes 116t formed in the pre-metal dielectric layer 104. The plurality of contact holes 116t may expose the gate electrodes of the respective gate patterns 110.

The plurality of conductive pads 120 and 125 may be formed on, for example, the pre-metal dielectric layer 104. For example, the plurality of conductive pads 120 and 125 may be formed on the corresponding gate patterns 110, and include the first conductive pad 120 and the second conductive pad 125. The conductive pads 120 and 125 may include, for example, at least one of aluminum, tungsten, and copper.

The first contacts 116 are formed in, for example, the plurality of contact holes 116t formed in the pre-metal dielectric layer 104. The plurality of first contacts 116 may, for example, electrically connect the corresponding gate patterns 110 to the conductive pads 120 and 125. The second contacts 114 formed in the pre-metal dielectric layer 104 may, for example, electrically connect the second wiring 114 to the source/drain 105.

The third barrier conductive film 150 may be formed, for example, inside a part of the plurality of contact holes 116t, and the fourth barrier conductive film 155 may be formed inside the remaining contact holes 116t. The third barrier conductive film 150 is formed, for example, on side surfaces and bottom surfaces of the contact holes 116t. The fourth barrier conductive film 155 is formed on, for example, the side surfaces of the contact holes 116t, but is not formed on the bottom surfaces of the contact holes 116t. Although the third barrier conductive film 150 and the fourth barrier conductive film 155 are illustrated as single layers, exemplary embodiments of the present invention are not limited thereto. For example, alternatively, in an embodiment the third barrier conductive film 150 and the fourth barrier conductive film 155 may be multi-layers.

That is, the third barrier conductive film 150 is formed on, for example, the bottom surfaces of a part of the plurality of contact holes 116t, and is interposed between the bottom surfaces of the first contacts 116 and the gate patterns 110. However, unlike the third barrier conductive film 150, the fourth barrier conductive film 155 is not formed on the bottom surfaces of the contact holes, and thus is not interposed between the bottom surfaces of the first contacts 116 and the gate patterns 110.

The third barrier conductive film 150 may be interposed between, for example, the first conductive pad 120 and the gate patterns 110, and the fourth barrier conductive film 155 may be interposed between the second conductive pad 125 and the gate pattern 110.

Referring to FIG. 7, in the contact hole 116t having a bottom surface on which the barrier conductive film is not formed, the first contact 116 may be formed to be in contact with the gate pattern 110. That is, in the contact hole 116t in which the fourth barrier conductive film 155 is formed, the first contact 116 may be formed to be in contact with the gate pattern 110.

Further, in the contact hole having the bottom surface on which the barrier conductive film is formed, that is, in the contact hole 116t in which the third barrier conductive film 150 is formed, the resistance between the first conductive pad 120 and the gate pattern 110 is a first resistance, and in the contact hole having the bottom surface on which the barrier conductive film is not formed, that is, in the contact hole 116t in which the fourth barrier conductive film 155 is formed, the resistance between the second conductive pad 125 and the gate pattern 110 is a second resistance.

If the resistivity of the material that is included in the third barrier conductive film 150 and the fourth barrier conductive film 155 is higher than the resistivity of the material that is included in the first contact 116, the first resistance may be higher than the second resistance. This is because the third barrier conductive film 150 having high resistivity is interposed between the first conductive pad 120 and the gate pattern 110.

Referring to FIGS. 2 to 4, and 8 to 12, a method for fabricating a mask ROM according to an embodiment of the present invention will be described.

FIGS. 8 to 12 are view of intermediate steps explaining a method for fabricating a mask ROM according to an embodiment of the present invention.

Referring to FIG. 8, an isolation film 102 is formed in a substrate 100 to define an active region. A gate pattern 110 is formed on the active region on the substrate 100, and a source/drain 105 is formed on both sides of the gate pattern 110.

A pre-metal dielectric layer 104 is formed on the substrate 100 and the gate pattern 110, and a first contact 116 and a second contact 114 are formed in the pre-metal dielectric insulating film 104. The first contact 116 is electrically connected to the gate pattern 110, and the second contact 114 is electrically connected to the source/drain 105.

Thereafter, a plurality of conductive pads 120 and 125 are formed on the substrate 100, that is, on the pre-metal dielectric layer 104. The plurality of conductive pads 120 and 125 are electrically connected to the corresponding gate patterns 110 through the first contacts 116. A second wiring 122 is electrically connected to the corresponding source/drain 105 through the second contact 114.

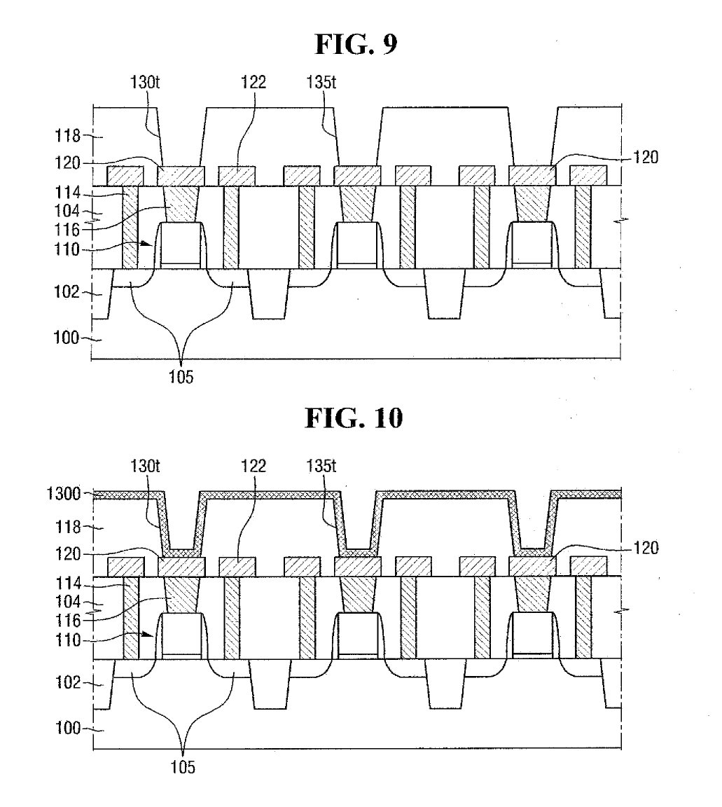

Referring to FIG. 9, an interlayer insulating film 118 that includes a plurality of via holes 130t and 135t is formed on the plurality of conductive pads 120 and 125 and the second wiring 122. The plurality of via holes 130t and 135t formed in the interlayer insulating film 118 expose the corresponding conductive pads 120 and 125, respectively.

The via holes 130t and 135t include the first via hole 130t and the second via hole 135t, and the first via hole 130t exposes the first conductive pad 120, and the second via hole 135t exposes the second conductive pad 125.

Referring to FIG. 10, a first conductive film 1300 is formed to cover side surfaces and bottom surfaces of the via holes 130t and 135t and to cover an upper surface of the interlayer insulating film 118. It is illustrated that the first conductive film 1300 is formed with a uniform thickness depending on the upper surface of the interlayer insulating film 118 and the via holes 130t and 135t, but exemplary embodiments of the present invention are not limited thereto. The first conductive film 1300 may include, for example, a material, such as Ta, TaN, Ti, TiN, Ru, Co, Ni, NiB, or WN.

In the method for fabricating a mask ROM according to embodiments of the present invention, it is described that only the first conductive film 1300 is formed, but exemplary embodiments of the present invention are not limited thereto. That is, for example, to protect the first conductive film 1300 that is formed on the side surface of the second via hole 135t in the following etching process, a uniform protection film (not illustrated) may be further formed on the first conductive film 1300.

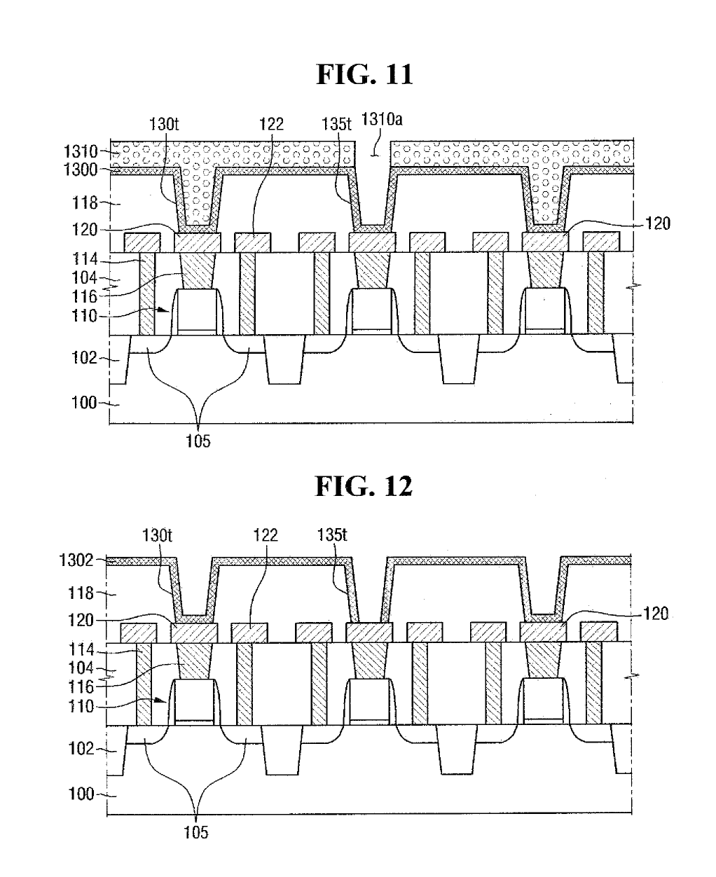

Referring to FIG. 11, a mask pattern 1310 including, for example, an opening 1310a is formed on the interlayer insulating film 118. The opening 1310a may expose a part of the plurality of via holes 130t and 135t. For example, the opening 1310a may be formed on the second via hole 135t, and may expose the first conductive film 1300 that is formed on the side surface and the bottom surface of the second via hole 135t.

For example, referring to FIGS. 11 and 12, using the mask pattern 1310 as an etching mask, at least a part of the first conductive film 1300, which is formed on the bottom surface of the exposed part of the via holes 130t and 135t, may be etched. Thereafter, the mask pattern 1310 used as the etching mask is removed. Through this, a second conductive film 1302 may be formed on the bottom surface of the second via hole 135t and the bottom surface of the first via hole 130t with different thicknesses, or the second conductive film 1302, from which all conductive films are removed, may be formed on the bottom surface of the second via hole 135t.

A method for removing the first conductive film 1300 formed on the bottom surface of the second via hole 135t may include, for example, at least one of dry etching and wet etching.

In the method for fabricating a mask ROM according to the present embodiment of the present invention, it is described that the second conductive pad 125 is exposed through removing the whole first conductive film 1300 formed on the bottom surface of the second via hole 135t, but exemplary embodiments of the present invention are not limited thereto. That is, for example, alternatively in an embodiment, only a part of the first conductive film 1300 formed on the bottom surface of the second via hole 135t may be removed. In this case, the mask ROM as described with reference to FIG. 5 can be fabricated.

Referring to FIGS. 2 and 3, vias 140 and 145 are formed on the plurality of conductive pads 120 and 125 by filling the via holes 130t and 135t with a conductive material. The first via 140 may be formed on the first conductive pad 120 by, for example, filling the first via hole 130t with a conductive material, and the second via 145 may be formed on the second conductive pads 125 by, for example, filling the second via hole 135t with a conductive material. The conductive material that fills the via holes 130t and 135t may include, for example, at least one of tungsten and copper.

In the method for fabricating a mask ROM according to the present embodiment of the present invention, as the second conductive pad 125 is exposed through removal of the whole conductive film formed on the bottom surface of the second via hole 135t, the second via 145 is formed to be in contact with the second conductive pad 125.

Thereafter, the plurality of first wirings 142 may be formed on the plurality of vias 140 and 145 and the interlayer insulating film 118. The first wirings 142 are formed side by side and spaced apart from each other, and are electrically connected to the corresponding vias 140 and 145.

Unlike FIG. 3, referring to FIG. 4, when the vias 140 and 145 are formed on the plurality of conductive pads 120 and 125 by filling the via holes 130t and 135t with a conductive material, an air gap 145a may be formed in the second via hole 135t.

By adjusting processing conditions when the plurality of vias 140 and 145 are formed in the via holes 130t and 135t, the air gap 145a may be formed in the second via 145 that is formed on the second conductive pad 125.

Referring to FIGS. 6, 8, 9, and 13 to 15, a method for fabricating a mask ROM according to an embodiment of the present invention will be described. The present embodiment is substantially the same as the above-described methods except for the point that the first conductive film is formed as a multi-layer in the present embodiment. Thus, the same reference numerals used in connection with the above-mentioned methods are used in the present embodiment to refer to the same elements, and the explanation thereof will be simplified or omitted.

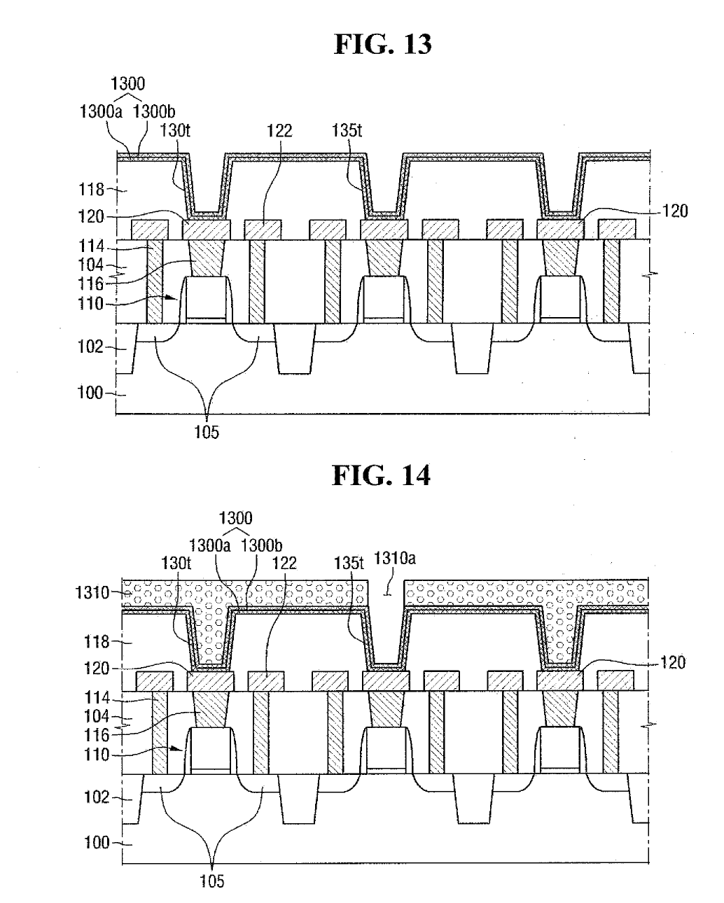

FIGS. 13 to 15 are views of intermediate steps explaining a method for fabricating a mask ROM according to an embodiment of the present invention.

Referring to FIG. 13, a first conductive film 1300 is formed to, for example, cover side surfaces and bottom surfaces of the via holes 130t and 135t and to cover an upper surface of the interlayer insulating film 118. The first conductive film 130 includes, for example, the first lower conductive film 1300a and the first upper conductive film 1300b, and the first lower conductive film 1300a and the first upper conductive film 1300b are sequentially formed. The first lower conductive film 1300a and the first upper conductive film 1300b may include, for example, a material, such as Ta, TaN, Ti, TiN, Ru, Co, Ni, NiB, or WN, and may include different materials.

Referring to FIG. 14, a mask pattern 1310 including, for example, an opening 1310a is formed on the interlayer insulating film 118. The opening 1310a may expose a part of the plurality of via holes 130t and 135t. For example, the opening 1310a may be formed on the second via hole 135t, and may expose the first conductive film 1300 that is formed on the side surface and the bottom surface of the second via hole 135t.

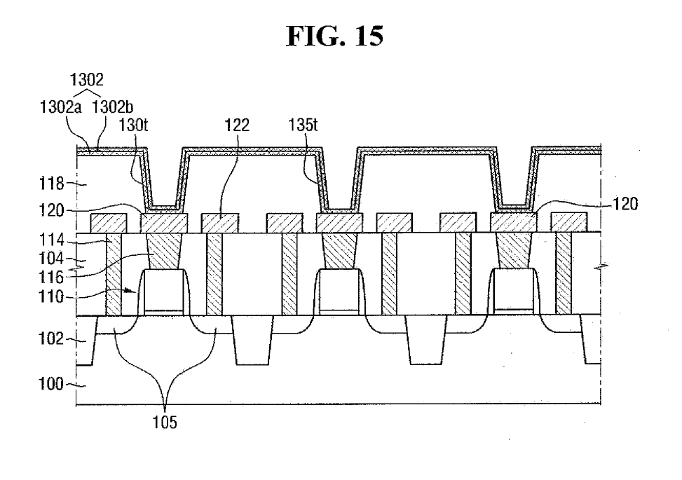

For example, referring to FIGS. 14 and 15, using the mask pattern 1310 as an etching mask, at least a part of the first conductive film 1300, which is formed on the bottom surface of the exposed part of the via holes 130t and 135t, may be etched. In other words, the first upper conductive film 1300b that is formed on the bottom surface of the second via hole 135t, among the first conductive film 1300 that is formed in the second via hole 135t exposed by the opening 1310a, may be removed through, for example, selective etching. Through this, the first lower conductive film 1300a is exposed. Thereafter, the mask pattern used as the etching mask is removed.

By removing the first upper conductive film 1300b formed on the bottom surface of the second via hole 135t, a second conductive film 1302 is formed.

Referring to FIG. 6, the first via 140 and the second via 145 are formed in the first via hole 130t and the second via hole 135t, respectively. Thereafter, the first wirings 142 are formed.

Having described exemplary embodiments of the present invention, it is further noted that it is readily apparent to those of ordinary skill in the art that various modifications may be made without departing from the spirit and scope of the invention which is defined by the metes and bounds of the appended claims

What is claimed is:

1. A mask read-only memory (ROM) comprising:
a plurality of conductive pads disposed on a substrate;
an insulating film disposed on the conductive pads;
a plurality of via holes disposed in the insulating film exposing the conductive pads;
a plurality of first wirings disposed side by side and spaced apart from each other on the insulating film;
a plurality of vias disposed in the via holes electrically connecting the conductive pads to the first wirings, respectively; and
at least one of barrier conductive film not disposed on a bottom surface of a part of the plurality of via holes between the vias and the conductive pads.

2. The mask ROM of claim 1, wherein in the via hole having the bottom surface on which the barrier conductive film is not disposed, the via is disposed in contact with the conductive pad.

3. The mask ROM of claim 1, further comprising an air gap disposed on the bottom surface of the via hole on which the barrier conductive film is not disposed.

4. The mask ROM of claim 1, wherein a resistance between the first wiring and the conductive pad is a first resistance in the via hole in which the barrier conductive film is disposed, wherein a resistance between the first wiring and the conductive pad is a second resistance in the via hole in which the barrier conductive film is not disposed, and wherein the first resistance and the second resistance are different from each other.

5. The mask ROM of claim 4, wherein the first resistance is higher than the second resistance.

6. The mask ROM of claim 1, further comprising a plurality of gate patterns disposed on lower portions of the conductive pads,
wherein the gate patterns are electrically connected to the corresponding conductive pads, respectively.

7. The mask ROM of claim 6, further comprising a source/drain disposed on opposing sides of the gate pattern, and a plurality of second wirings electrically connected to the source/drain.

8. The mask ROM of claim 1, wherein the via includes one of tungsten or copper, and the barrier conductive film includes at least one of titanium and tantalum.

9. A mask read-only memory (ROM) comprising:
a first conductive pad and a second conductive pad disposed on a substrate;
an insulating film disposed on the first conductive pad and the second conductive pad;
a first via hole and a second via hole disposed in the insulating film exposing the first conductive pad and the second conductive pad;
a plurality of first wirings disposed side by side and spaced apart from each other on the insulating film;
a first via disposed in the first via hole electrically connecting the first conductive pad to the first wirings;
a second via disposed in the second via hole electrically connecting the second conductive pad to the first wirings;
a first barrier conductive film disposed on a bottom surface of the first via hole between the first via and the first conductive pad, wherein the first barrier conductive film has a first thickness; and
a second barrier conductive film disposed on a bottom surface of the second via hole between the second via and the second conductive pad, and wherein the second barrier conductive film has a second thickness that is different from the first thickness.

10. The mask ROM of claim 9, wherein the first thickness is larger than the second thickness.

11. The mask ROM of claim 10, wherein a resistance between the first wiring and the first conductive pad is a first resistance, wherein a resistance between the first wiring and the second conductive pad is a second resistance, and wherein the first resistance is higher than the second resistance.

12. The mask ROM of claim 10, wherein the first barrier conductive film includes a first film and a second film, and the second bather conductive film does not include the second film.

13. The mask ROM of claim 10, wherein the first barrier conductive film and the second barrier conductive film include substantially the same material as each other.

14. The mask ROM of claim 9, further comprising a plurality of gate patterns disposed on lower portions of the first conductive pad and the second conductive pad,
wherein the gate patterns are electrically connected to the corresponding first conductive pad and second conductive pad, respectively.

15. The mask ROM of claim 14, further comprising a source/drain disposed on opposing sides of the gate pattern, and a plurality of second wirings electrically connected to the source/drain.

16. The mask ROM of claim 15, further comprising:
a pre-metal dielectric layer disposed on the gate patterns, wherein the pre-metal dielectric layer includes a first contact hole and a second contact hole therein exposing a portion of the gate patterns,
a plurality of first contacts disposed in the first and second contact holes in the pre-metal dielectric layer which electrically connect the gate patterns to the first conductive pad and the second conductive pad, and
a plurality of second contacts disposed in the pre-metal dielectric layer which electrically connect the second wirings to the source/drain.

17. The mask ROM of claim 16, further comprising:
a third barrier conductive film disposed in the first contact hole on opposing side surfaces of the first contact hole and on a bottom surface of the first contact hole;
a fourth barrier conductive film disposed in the second contact hole on opposing side surfaces of the second contact hole and wherein the fourth barrier conductive film is not disposed on a bottom surface of the second contact hole.

18. The mask ROM of claim 17, wherein one of the first contacts contacts one of the gate patterns through the bottom surface of the second contact hole on which the fourth barrier conductive film is not disposed.

19. The mask ROM of claim 17, wherein the third barrier conductive film and the fourth barrier conductive film each include a material having a higher resistivity than a resistivity of a material included in the first contacts.

20. A mask read only memory (ROM) comprising:
a first conductive pad and a second conductive pad disposed on a substrate;
an interlayer insulating film disposed on the first conductive pad and the second conductive pad;
a first via hole and a second via hole disposed in the interlayer insulating film exposing the first conductive pad and the second conductive pad;
a plurality of first wirings disposed side by side and spaced apart from each other on the insulating film;
a first via disposed in the first via hole electrically connecting the first conductive pad to the first wirings;
a second via disposed in the second via hole electrically connecting the second conductive pad to the first wirings;
a first barrier conductive film comprising a first lower bottom barrier conductive film and a first upper bottom barrier conductive film sequentially disposed on a bottom surface of the first via hole between the first via and the first conductive pad and a first lower side barrier conductive film and a first upper side barrier conductive film sequentially disposed on opposing side surfaces of the first via hole between the first via and the interlayer insulating film; and
a second barrier conductive film comprising a second lower bottom barrier conductive film disposed on a bottom surface of the second via hole between the second via and second conductive pad and a second lower side barrier conductive film and a second upper side barrier conductive barrier sequentially disposed on opposing side surfaces of the second via hole between the second via and the interlayer insulating film,
wherein a thickness of the first lower bottom barrier conductive film and the first upper bottom barrier conductive film sequentially disposed on the bottom surface of the first via hole is larger than a thickness of the second lower bottom barrier conductive film disposed on the bottom surface of the second via hole.
